(19) United States
(12) Patent Application Publication
(10) Pub. No.: US 2019/0051846 A1
(43) Pub. Date: Feb. 14, 2019

(54) ORGANIC LIGHT-EMITTING DEVICE

(71) Applicants: Cambridge Display Technology Limited, Godmanchester (GB); Sumitomo Chemical Company, Ltd, Tokyo (JP)

(72) Inventors: William Tarran, Godmanchester (GB); Kiran Kamtekar, Godmanchester (GB)

(73) Assignees: Cambridge Display Technology Limited, Godmanchester (GB); Sumitomo Chemical Company Limited, Tokyo (JP)

(21) Appl. No.: 16/083,475

(22) PCT Filed: Mar. 9, 2017
(86) PCT No.: PCT/GB2017/050633

§ 371 Date: Sep. 7, 2018

(30) Foreign Application Priority Data
Mar. 11, 2016 (GB) 1604199.8

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

An organic white light-emitting device comprising an anode, a cathode and at least one light-emitting layer between the anode and the cathode, wherein a first light-emitting layer comprises a first light-emitting compound of formula (I): wherein R¹, R² and R³ independently in each occurrence is a substituent; M¹ is a transition metal; L¹ is a ligand other than a ligand of formula: (II) a and b are each 0 or a positive integer; x is at least 1; and y is 0 or a positive integer, a light-emitting layer of the device comprising at least one further light-emitting material.

### FIELD OF THE INVENTION

The present invention relates to white organic light-emitting devices; light-emitting materials for said devices; and methods of making said light-emitting devices.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Suitable light-emitting materials include small molecule, polymeric and dendrimeric materials. Suitable light-emitting polymers include poly(arylene vinylenes) such as poly(p-phenylene vinylenes) and polyarylenes such as polyfluorenes.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

US 2007/0190359 discloses compounds having a ligand selected from ligands of the following formulae:

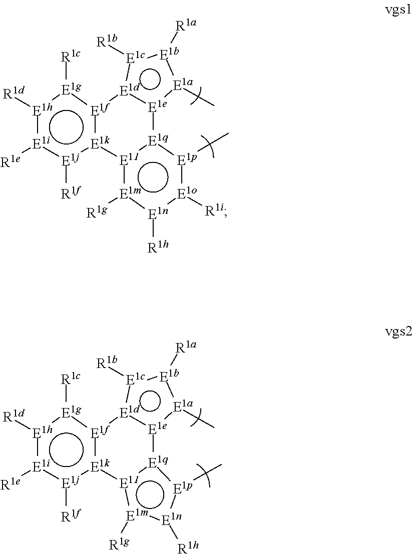

WO 2010/032663 discloses compounds of formulae (A)-(D):

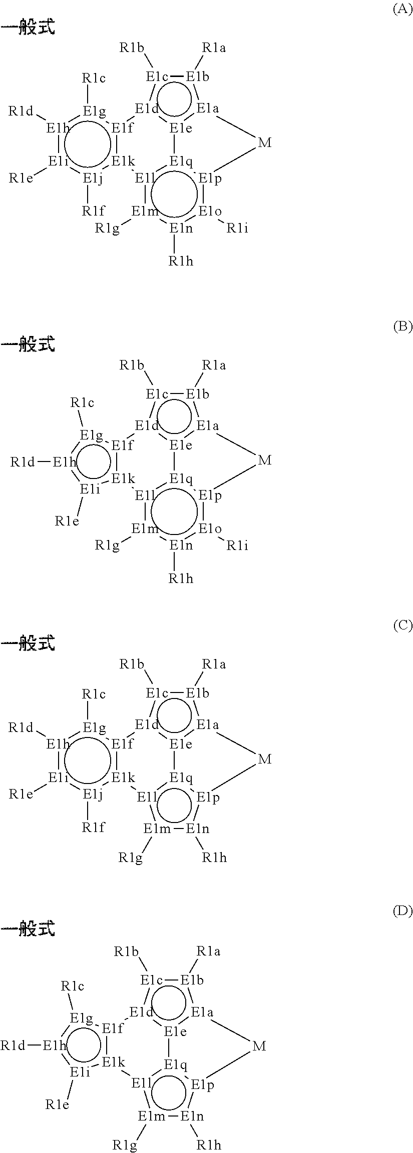

JP 2011/187783 discloses compounds having a ligand selected from formula:

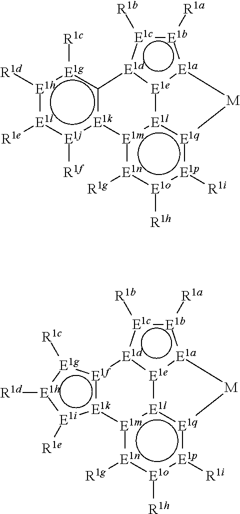

US 2015/221878 discloses organometallic compounds comprising a ligand of formula 2 and a ligand of formula 3:

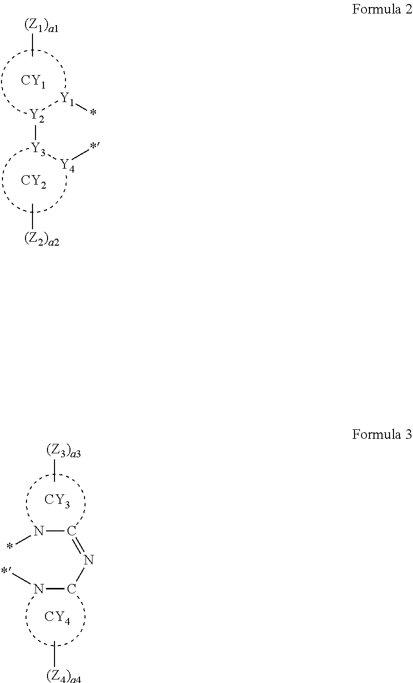

A plurality of light-emitting materials may be used to produce white light from an OLED.

White light can range from “warm” white light, which is light having a relatively low colour coordination temperature (CCT) to “cool” white light having a relatively high CCT, however there remains a need for relatively high CCT white OLEDs.

It is an object of the invention to provide a white OLED having a high CCT.

It is a further object of the invention to provide phosphorescent light-emitting compounds having deep blue emission.

### SUMMARY OF THE INVENTION

An organic white light-emitting device comprising an anode, a cathode and at least one light-emitting layer between the anode and the cathode, wherein a first light-emitting layer comprises a first light-emitting compound of formula (I):

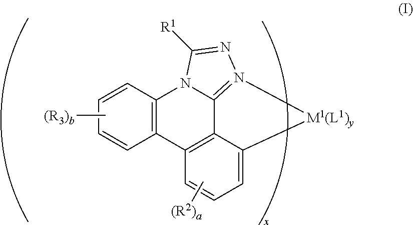

wherein R¹, R² and R³ independently in each occurrence is a substituent;
M¹ is a transition metal;
L¹ is a ligand other than a ligand of formula:

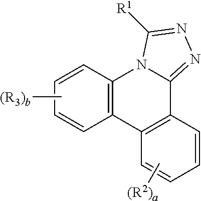

a is 0 or a positive integer;
b is 0 or a positive integer;
x is at least 1; and
y is 0 or a positive integer, a light-emitting layer of the device comprising at least one further light-emitting material.

In a second aspect the invention provides a method of forming an organic light-emitting device according to the first aspect, the method comprising the step of depositing the first light-emitting layer over one of the anode and cathode, and depositing the other of the anode and cathode over the light-emitting layer.

### DESCRIPTION OF THE DRAWINGS

The invention will now be described in more detail with reference to the Figures, in which:

FIG. 1 illustrates an OLED according to an embodiment of the invention; and

FIG. 2 shows photoluminescence spectra for a material according to an embodiment of the invention and two comparative materials.

### DETAILED DESCRIPTION OF THE INVENTION

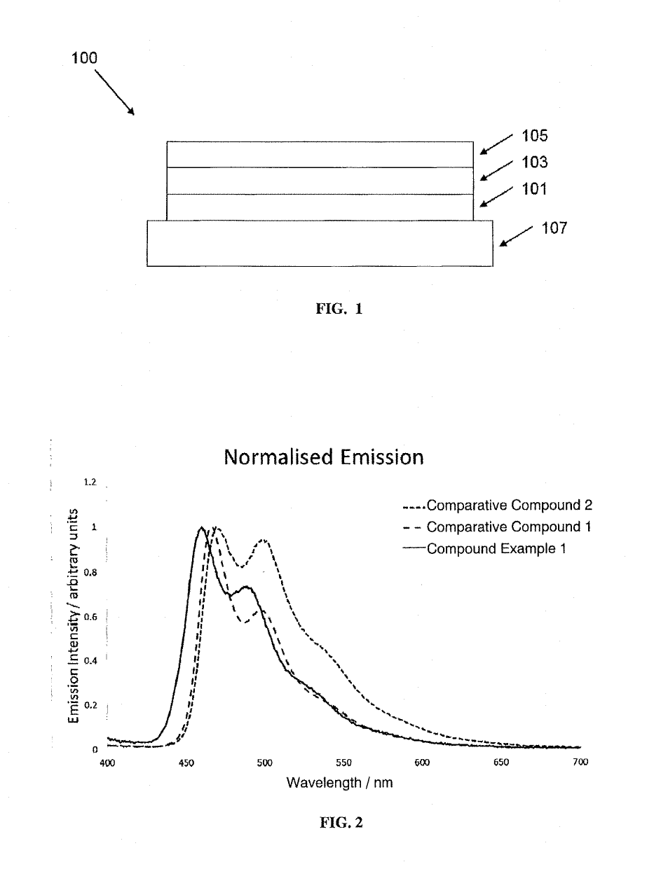

FIG. 1, which is not drawn to any scale, illustrates schematically an OLED 100 according to an embodiment of the invention. The OLED 100 is carried on substrate 107 and comprises an anode 101, a cathode 105 and a first light-emitting layer 103 between the anode and the cathode. Further layers (not shown) may be provided between the anode and the cathode.

Light-emitting layer 103 contains a phosphorescent compound of formula (I), and preferably contains a host material. Triplet excitons formed by recombination of holes and electrons decay from a lowest triplet excited state (T¹) of the phosphorescent compound to produce phosphorescence.

The device emits white light when in use.

In one embodiment, light-emitting layer 103 is the only light-emitting layer of the device and light-emitting layer 103 comprises at least one further light-emitting material which emits light when the device is in use to produce white light when combined with emission from the compound of formula (I).

In other preferred embodiments the device comprises at least one further light-emitting layer containing at least one further light-emitting material.

The further light-emitting material or materials may independently be selected from fluorescent and phosphorescent emitters.

Preferably, all light-emitting materials of the device are phosphorescent emitters and all light emitted from the device when in use is phosphorescence.

The photoluminescence spectrum of the compound of formula (I) is preferably no more than, and preferably less than, 465 nm.

Optionally, the device comprises a yellow further light-emitting material, the emission of the compound of formula (I) and the yellow further light-emitting material combining to produce white light when the device is in use.

Optionally, the device comprises a green further light-emitting material and a red further light-emitting material, the emission of the compound of formula (I), the green further light-emitting material and the red further light-emitting material combining to produce white light when the device is in use.

A green emitting material as described herein optionally has a photoluminescent spectrum with a peak in the range of more than about 490 nm, optionally more than about 500 nm, up to about 560 nm, optionally up to about 540 nm

A yellow emitting material as described herein optionally has a photoluminescent spectrum with a peak in the range of more than about 560 nm up to about 590 nm.

A red emitting material as described herein optionally has a peak in its photoluminescent spectrum of more than about 590 nm up to about 700 nm, optionally up to about 650 nm.

If present further layers between the anode and the cathode, in addition to the first light-emitting layer, may be selected from, without limitation, a hole-transporting layer comprising a hole-transporting material; an electron-transporting layer comprising an electron-transporting material; hole-blocking layer comprising a hole-blocking material; an electron-blocking layer comprising an electron-blocking material; hole-injection layers; and electron-injection layers.

Exemplary OLED structures including one or more further layers include the following:
Anode/Hole-injection layer/Light-emitting layer/Cathode
Anode/Hole transporting layer/Light-emitting layer/Cathode
Anode/Hole-injection layer/Hole-transporting layer/Light-emitting layer/Cathode
Anode/Hole-injection layer/Hole-transporting layer/Light-emitting layer/Electron-transporting layer/Cathode.
Anode/Hole-injection layer/Hole-transporting layer/Light-emitting layer/Electron-transporting layer/Electron-injection layer/Cathode.

A charge-transporting or charge-blocking layer may comprise one or more further light-emitting materials, making it a further light-emitting layer.

Optionally, the compound of formula (I) and the further light-emitting material(s) are provided in one of the following arrangements:
Red further light-emitting material, green further light-emitting material and compound of formula (I) in the first light-emitting layer.
Yellow further light-emitting material and compound of formula (I) in the first light-emitting layer.
Green further light-emitting material and compound of formula (I) in the first light-emitting layer and red further light-emitting material in a further light-emitting layer.
A compound of formula (I) in the first light-emitting layer and a yellow light-emitting material in a further light-emitting layer.
A compound of formula (I) in the first light-emitting layer, a red light-emitting material in a first further light-emitting layer and a green light-emitting material in a second further light-emitting layer.

Preferably, the OLED comprises a compound of formula (I), a red light-emitting material and a green light-emitting material.

If the device comprises more than one light-emitting layer then the light-emitting layers are preferably adjacent layers.

Optionally, the device comprises a hole-transporting layer between the anode and the first light-emitting layer and a further light-emitting material is provided in one or both of the hole-transporting layer, making the hole-transporting layer a further light-emitting layer, and the first light-emitting layer containing the phosphorescent compound of formula (I).

Optionally, a first further light-emitting material, preferably a green light-emitting material, is provided in the first light-emitting layer and a second further light-emitting material, preferably a red light-emitting material, is provided in the hole-transporting layer.

The compound of formula (I) optionally forms about 0.5 weight % of the first light-emitting layer, optionally at least 1 weight % or at least 10 weight %.

The compound of formula (I) optionally forms up to about 50 weight %, optionally up to about 40 weight % or 30 weight % of the first light-emitting layer.

Preferably, the CCT of the white device is at least 3000K, optionally at least 3500K, 4000K or 4500K. Deviation from the Planckian locus, Δuv, is preferably less than 0.01.

Preferably, the colour rendering index (CRI) of the white device at a CCT of at least 3000K is at least 80.

### Compounds of Formula (I)

Metal M¹ of the phosphorescent compound of formula (I) may be any suitable transition metal, for example a transition metal of the second or third row of the d-block elements (Period 5 and Period 6, respectively, of the Periodic Table). Exemplary metals include Ruthenium, Rhodium, Palladium, Silver, Tungsten, Rhenium, Osmium, Iridium, Platinum and Gold. Preferably, M¹ is Ir³⁺.

The compound of formula (I) contains at least one ligand of formula:

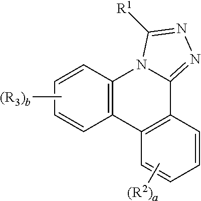

Ligand L¹, if present, may be a monodentate or polydentate ligand. Optionally, L¹ is a bidentate ligand. Optionally, L¹ is selected from O,O cyclometallating ligands, optionally diketonates, optionally acac; N,O cyclometallating ligands, optionally picolinate; and N,N cyclometallating ligands. If more than one ligand L¹ is present then the ligands L¹ may be the same or different.

Optionally, y is 0.

Optionally, x is 3.

R¹ may be selected from the group consisting of:
C₁₋₂₀ alkyl wherein one or more non-adjacent C atoms of the C₁₋₂₀ alkyl may be replaced with —O—, —S— —SiR⁴₂— or —COO— and one or more H atoms may be replaced with F, wherein R4 in each occurrence is independently a substituent, preferably a C₁₋₂₀ hydrocarbyl group, optionally a hydrocarbyl group selected from C₁₋₁₂ alkyl and phenyl which may be unsubstituted or substituted with one or more C₁₋₁₂ alkyl groups; and
a group of formula -(Ar¹)p wherein Ar¹ in each occurrence is a C₆₋₂₀ aryl group or a 5-20 membered heteroaryl group that may be unsubstituted or substituted with one or more substituents; and p is at least 1, optionally 1, 2 or 3.

“Aryl” and “heteroaryl” as used herein includes monocyclic and polycyclic aromatic and heteroaromatic groups.

Preferably, R¹ is selected from C₃₋₂₀ alkyl, preferably branched C₃₋₂₀ alkyl, and —(Ar¹)ₚ wherein Ar¹ in each occurrence is a C₆₋₂₀ aryl group that may be unsubstituted or substituted with one or more substituents.

Preferably, the or each group Ar¹ is phenyl which may be unsubstituted or substituted with one or more substituents.

—(Ar¹)ₚ may be selected from groups of formula:

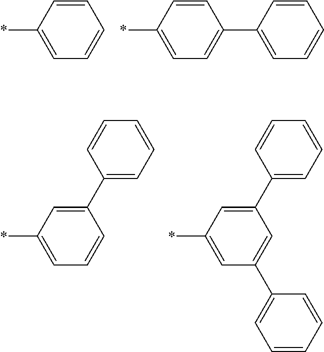

wherein each phenyl group may be unsubstituted or substituted with one or more substituents.

Preferred substituents of the or each Ar¹ of -(Ar¹)ₚ are selected from C₁₋₁₂ alkyl wherein one or more non-adjacent C atoms of the C₁₋₂₀ alkyl may be replaced with —O—, —S— or —COO— and one or more H atoms may be replaced with F.

Preferably, one or both of the ring atoms of -(Ar¹)ₚ adjacent to the ring atom that is bound to the triazolophenanthridine group of formula (I) is substituted. Such substituents may limit the extent of conjugation between the triazolophenanthridine group and Ar¹.

If present, R² and R³ may independently in each occurrence be selected from the group consisting of:
C₁₋₂₀ alkyl wherein one or more non-adjacent C atoms of the C₁₋₂₀ alkyl may be replaced with —O—, —S— or —COO— and one or more H atoms may be replaced with F; and
a group of formula -(Ar²)q wherein Ar² in each occurrence is a C₆₋₂₀ aryl group or a 5-20 membered heteroaryl group that may be unsubstituted or substituted with one or more substituents; and q is at least 1, optionally 1, 2 or 3.

Preferably, R² and R³ are each independently selected from C₃₋₂₀ alkyl, preferably branched C₃₋₂₀ alkyl, and —(Ar²)_{q} wherein Ar² in each occurrence is a C₆₋₂₀ aryl group that may be unsubstituted or substituted with one or more substituents.

Preferably, the or each group Ar² is phenyl which may be unsubstituted or substituted with one or more substituents.

—(Ar²)_{q} may be selected from groups of formula:

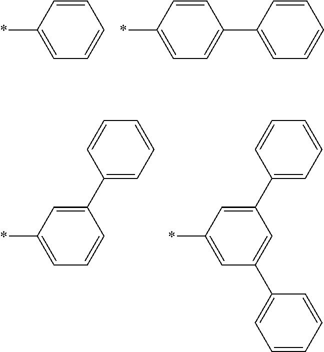

wherein each phenyl group may be unsubstituted or substituted with one or more substituents.

Preferred substituents of the or each Ar² of -(Ar²)_{q} are selected from C₁₋₁₂ alkyl wherein one or more non-adjacent C atoms of the C₁₋₂₀ alkyl may be replaced with —O—, —S— or —COO— and one or more H atoms may be replaced with F.

Optionally, b is 1.

Optionally, the compound of formula (I) has formula (Ia):

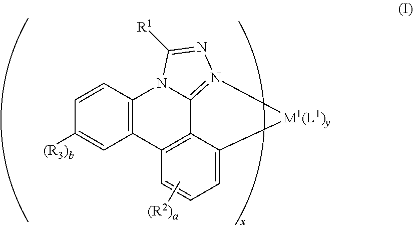

Optionally, a of formula (I) or formula (Ia) is 0.

Exemplary compounds of formula (I) include the following:

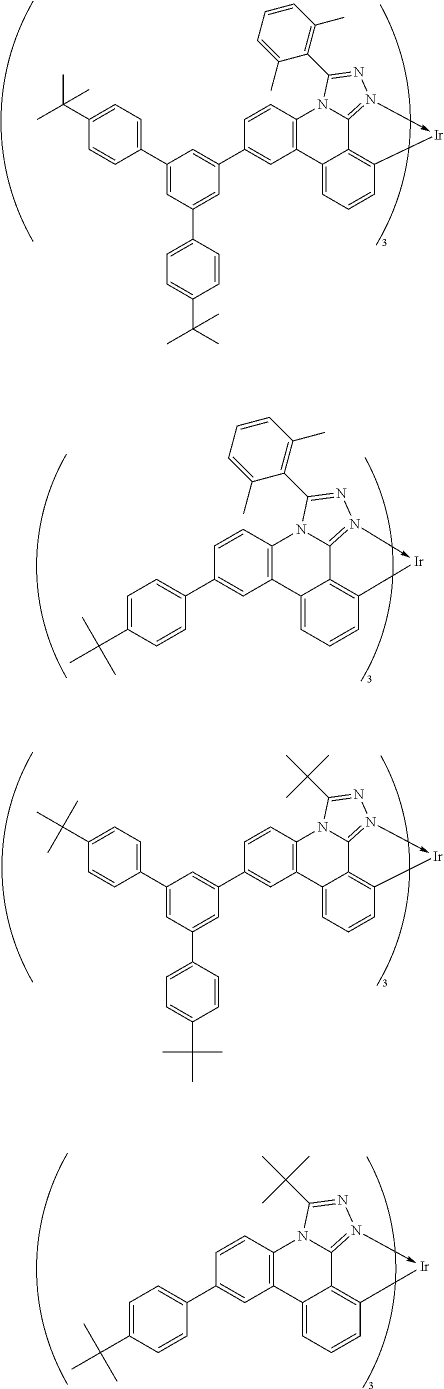

### Host Materials

The host material of the first light-emitting layer has a triplet excited state energy level T₁ that is no more than 0.1 eV lower than, and preferably at least the same as or higher than, the phosphorescent compound of formula (I) in order to allow transfer of triplet excitons from the host material to the phosphorescent compound of formula (I).

The host material may be a polymer or a non-polymeric compound.

An exemplary non-polymeric host material is an optionally substituted compound of formula (X):

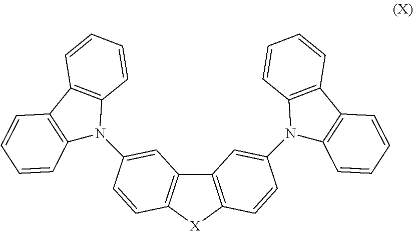

wherein X is O or S.

Each of the benzene rings of the compound of formula (X) may independently be unsubstituted or substituted with one or more substituents. Substituents may be selected from C₁₋₂₀ alkyl wherein one or more non-adjacent C atoms of the alkyl may be replaced with O, S, COO, C═O or Si(R⁹)₂ wherein the groups R⁹ are the same or different and are selected from C₁₋₂₀ hydrocarbyl, optionally C₁₋₂₀ alkyl; unsubstituted phenyl; and phenyl substituted with one or more C₁₋₁₂ alkyl groups.

The compound of formula (I) may be mixed with the host material or may be covalently bound to the host material. In the case where the host material is a polymer, the metal complex may be provided as a main chain repeat unit, a side group of a repeat unit, or an end group of the polymer.

In the case where the compound of formula (I) is provided as a side group of a polymeric host, the metal complex may be directly bound to a main chain of the polymer or spaced apart from the main chain by a spacer group. A spacer group may be a C₁₋₂₀ alkylene chain or a phenylene-C₁₋₂₀-alkylene chain wherein one or more non-adjacent atoms of the alkylene chain may be replaced with O, S, CO or COO. The polymer main chain or spacer group may be bound to the triazolophenanthridine ligand of formula (I) or (if present) ligand L¹ of the compound of formula (I).

Exemplary host polymers include polymers having a non-conjugated backbone with charge-transporting groups pendant from the non-conjugated backbone, for example poly(9-vinylcarbazole), and polymers comprising conjugated repeat units in the backbone of the polymer. If the backbone of the polymer comprises conjugated repeat units then the extent of conjugation between repeat units in the polymer backbone may be limited in order to maintain a triplet energy level of the polymer that is no lower than that of the phosphorescent compound of formula (I).

Exemplary repeat units of a conjugated polymer include unsubstituted or substituted monocyclic and polycyclic heteroarylene repeat units; unsubstituted or substituted monocyclic and polycyclic arylene repeat units as disclosed in for example, Adv. Mater. 2000 12(23) 1737-1750 and include: 1,2-, 1,3- and 1,4-phenylene repeat units as disclosed in J. Appl. Phys. 1996, 79, 934; 2,7-fluorene repeat units, for example as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer. Preferred substituents are selected from C₁₋₄₀ hydrocarbyl groups.

### Further Light-Emitting Materials

Further light-emitting materials may each independently be selected from fluorescent and phosphorescent materials.

Further light-emitting materials may each independently be non-polymeric or polymeric.

Further light-emitting materials are preferably non-polymeric phosphorescent materials.

Exemplary phosphorescent further light-emitting materials have formula (IX):

M²L²ₖL³₁L⁴ₘ (IX)

wherein M² is a transition metal; each of L², L³ and L⁴ is a coordinating group that independently may be unsubstituted or substituted with one or more substituents; k is a positive integer; l and m are each independently 0 or a positive integer; and the sum of (a. k)+(b. l)+(c.m) is equal to the number of coordination sites available on M², wherein a is the number of coordination sites on L², b is the number of coordination sites on L³ and c is the number of coordination sites on L⁴.

a, b and c are preferably each independently 1, 2 or 3. Preferably, L², L³ and L⁴ are each a bidentate ligand (a, b and c are each 2).

In a preferred embodiment, k is 3 and 1 and m are 0. In another preferred embodiment, k is 1 or 2; l is 1; and m is 0.

M² is preferably selected from row 2 and 3 d-block elements, preferably from ruthenium, rhodium, palladium, rhenium, osmium, iridium, platinum and gold. M² is preferably Ir³⁺

Exemplary ligands L², L³ and L⁴ include ligands comprising carbon or nitrogen donor atoms such as porphyrin or bidentate ligands of formula (X):

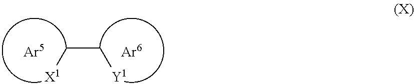

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together.

Ligands wherein X¹ is carbon and Y¹ is nitrogen are preferred,

Aryl groups Ar⁵ are preferably selected from C₆₋₂₀ aryl groups, optionally phenyl or naphthyl.

Heteroaryl groups Ar⁶ are preferably selected from C₅₋₂₀ heteroaryl groups, preferably C₅₋₂₀ heteroaryl groups of C and N atoms only or heteroaryl groups of C, N and S atoms only, optionally pyridyl, quinoline or isoquinoline.

Each of Ar⁵ and Ar⁶ may carry one or more substituents. Two or more of these substituents may be linked to form a ring, for example an aromatic ring.

Preferred substituents are selected from D, F, C₁₋₂₀ alkyl groups wherein one or more non-adjacent C atoms may be replaced with O, S, CO or COO and one or more H atoms may be replaced with F; phenyl or biphenyl that may be unsubstituted or substituted with one or more substituents, optionally one or more C₁₋₁₂ alkyl or C₁₋₁₂ alkoxy groups; and dendrons.

To achieve red emission, Ar⁵ may be selected from phenyl, fluorene, naphthyl and Ar⁶ are selected from quinoline, isoquinoline, thiophene and benzothiophene.

To achieve green emission, Ar⁵ may be selected from phenyl or fluorene and Ar⁶ may be pyridine.

Examples of bidentate ligands of formula (X) wherein X¹ is carbon and Y¹ is nitrogen are:

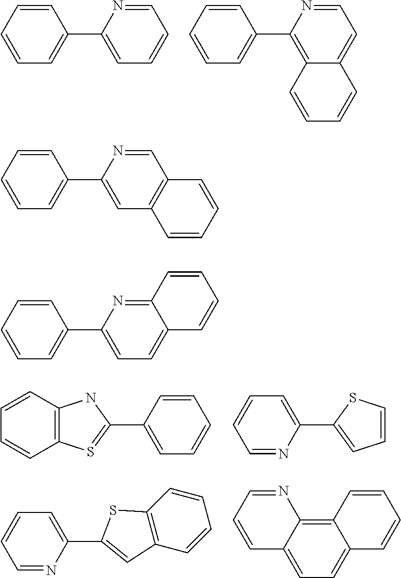

Other ligands suitable for use with d-block elements include O,O-bidentate ligands, optionally diketonates, O,N-bidentate ligands and N,N bidentate ligands, in particular acetylacetonate (acac), tetrakis-(pyrazol-1-yl)borate, 2-carboxypyridyl, triarylphosphines and pyridine, each of which may be substituted.

One or more of L², L³ and L⁴ may comprise a carbene group.

Dendrons as described herein comprise a branching point attached to a ligand of the metal complex and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example C₁₋₂₀ alkyl or alkoxy.

A dendron may have optionally substituted formula (XI)

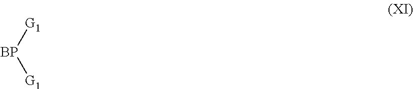

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (XIa):

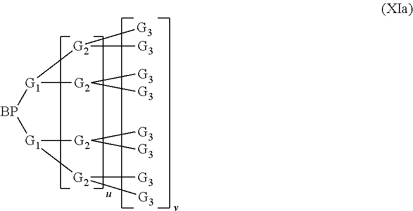

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

A preferred dendron is a substituted or unsubstituted dendron of formula (XIb):

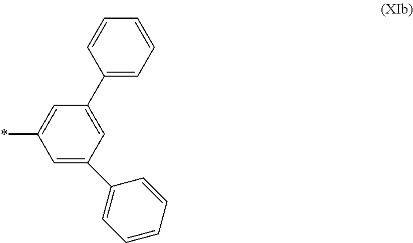 [SMILES: *c1cc(-c2ccccc2)cc(-c2ccccc2)c1]

wherein * represents an attachment point of the dendron to a ligand.

BP and/or any group G may be substituted with one or more substituents, for example one or more C₁₋₂₀ alkyl or alkoxy groups.

Further light-emitting materials of formula (IX) may be provided in the first light-emitting layer or in a further light-emitting layer.

One or more further light-emitting materials in the first light-emitting layer may independently be mixed with a host material of the first light-emitting layer or may be covalently bound thereto. In the case of a polymeric host, one or more further light-emitting materials may be provided in a side-group or end group of the polymeric host or as a repeat unit in a backbone of the polymeric host. A further light-emitting material provided as a side-group of a polymeric host may be directly bound to a backbone of the polymer or spaced apart therefrom by a spacer group. A spacer group may be a C₁₋₂₀ alkylene chain or a phenylene-C₁₋₂₀-alkylene chain wherein one or more non-adjacent atoms of the alkylene chain may be replaced with O, S, CO or COO.

### Charge Transporting and Charge Blocking Layers

A hole transporting layer may be provided between the anode of an OLED and the first light-emitting layer containing a compound of formula (I).

An electron transporting layer may be provided between the cathode of an OLED and the first light-emitting layer containing a compound of formula (I).

An electron blocking layer may be provided between the anode and the first light-emitting layer.

A hole blocking layer may be provided between the cathode and the first light-emitting layer.

Transporting and blocking layers may be used in combination. Depending on its HOMO and LUMO levels, a single layer may both transport one of holes and electrons and block the other of holes and electrons.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. The crosslinkable group may be provided as a substituent pendant from the backbone of a charge-transporting or charge-blocking polymer. Following formation of a charge-transporting or charge blocking layer, the crosslinkable group may be crosslinked by thermal treatment or irradiation.

If present, a hole transporting layer located between the anode and the light-emitting layer containing the compound of formula (I) preferably contains a hole-transporting material having a HOMO level of less than or equal to 5.5 eV, more preferably around 4.8-5.5 eV as measured by square wave voltammetry. The HOMO level of the hole transporting material of the hole-transporting layer may be selected so as to be within 0.2 eV, optionally within 0.1 eV, of the compound of formula (I) in order to provide a small barrier to hole transport.

A hole transporting layer may contain a hole-transporting (hetero)arylamine, such as a homopolymer or copolymer comprising hole transporting repeat units of formula (IX):

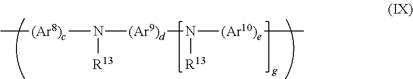

wherein Ar⁸, Ar⁹ and Ar¹⁰ in each occurrence are independently selected from substituted or unsubstituted aryl or heteroaryl, g is 0, 1 or 2, preferably 0 or 1, R¹³ independently in each occurrence is H or a substituent, preferably a substituent, and c, d and e are each independently 1, 2 or 3.

R¹³, which may be the same or different in each occurrence when g is 1 or 2, is preferably selected from the group consisting of alkyl, for example C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar¹⁰ and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ aryl, more preferably phenyl, that may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R¹³ is preferably Ar¹¹ or a branched or linear chain of Ar¹¹ groups. Ar¹¹ in each occurrence is preferably phenyl that may be unsubstituted or substituted with one or more substituents.

Exemplary groups R¹³ include the following, each of which may be unsubstituted or substituted with one or more substituents, and wherein * represents a point of attachment to N:

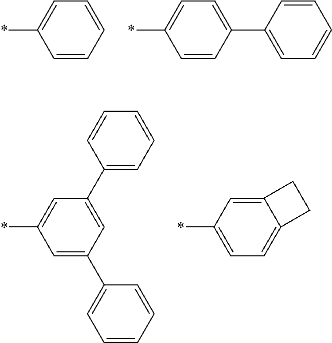

c, d and e are preferably each 1.

Ar⁸, Ar⁹, and, if present, Ar¹⁰ and Ar¹¹ are each independently unsubstituted or substituted with one or more, optionally 1, 2, 3 or 4, substituents. Optionally, substituents are selected from substituted or unsubstituted alkyl, optionally C₁₋₂₀ alkyl, wherein one or more non-adjacent C atoms may be replaced with optionally substituted aryl or heteroaryl (preferably phenyl), O, S, C═O or —COO— and one or more H atoms may be replaced with F.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (IX) include unsubstituted or substituted units of formulae (IX-1), (IX-2) and (IX-3):

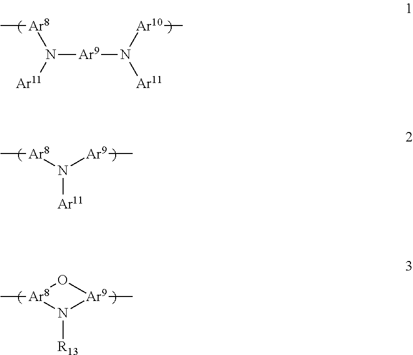

Exemplary copolymers comprise repeat units of formula (IX) and optionally substituted (hetero)arylene co-repeat units, such as phenyl, fluorene or indenofluorene repeat units as described above, wherein each of said (hetero)arylene repeat units may optionally be substituted with one or more substituents such as C₁₋₂₀ alkyl or C₁₋₂₀ alkoxy groups. Specific exemplary co-repeat units include fluorene repeat units and phenylene repeat units as described above with reference to the host materials. A hole-transporting copolymer containing repeat units of formula (IX) may contain 25-95 mol % of repeat units of formula (IX).

If present, an electron transporting layer located between the light-emitting layers and cathode preferably has a LUMO level of around 2.5-3.5 eV as measured by square wave square wave voltammetry. An electron transporting layer may contain a polymer comprising a chain of optionally substituted arylene repeat units, such as a chain of fluorene repeat units.

One or more further light-emitting materials in a charge-transporting layer may independently be mixed with a charge-transporting material of the charge-transporting layer or may be covalently bound thereto. In the case of a polymeric charge-transporting material, one or more further light-emitting materials may be provided in a side-group or end group of the polymeric charge-transporting material or as a repeat unit in a backbone of the polymeric charge-transporting material. A further light-emitting material provided as a side-group of a polymeric charge-transporting material may be directly bound to a backbone of the polymer or spaced apart therefrom by a spacer group. A spacer group may be a C₁₋₂₀ alkylene chain or a phenylene-C₁₋₂₀-alkylene chain wherein one or more non-adjacent atoms of the alkylene chain may be replaced with O, S, CO or COO.

### Hole Injection Layers

A conductive hole injection layer, which may be formed from a conductive organic or inorganic material, may be provided between the anode and the light-emitting layer or layers to assist hole injection from the anode into the layer or layers of semiconducting polymer. A hole transporting layer may be used in combination with a hole injection layer.

Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

### Cathode

The cathode is selected from materials that have a work function allowing injection of electrons into the light-emitting layer or layers. Other factors influence the selection of the cathode such as the possibility of adverse interactions between the cathode and the light-emitting materials. The cathode may consist of a single material such as a layer of aluminium. Alternatively, it may comprise a plurality of metals, for example a bilayer of a low work function material and a high work function material such as calcium and aluminium as disclosed in WO 98/10621. The cathode may contain a layer containing elemental barium, for example as disclosed in WO 98/57381, Appl. Phys. Lett. 2002, 81(4), 634 and WO 02/84759. The cathode may contain a thin (e.g. 1-5 nm thick) layer of metal compound between the light-emitting layer(s) of the OLED and one or more conductive layers of the cathode, such as one or more metal layers. Exemplary metal compounds include an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a work function of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate 107 preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Solution Processing

Suitable solvents for forming solution processable formulations of the light-emitting metal complex of formula (I) and compositions thereof may be selected from common organic solvents, such as mono- or poly-alkylbenzenes such as toluene and xylene and mono- or poly-alkoxybenzenes, and mixtures thereof.

Exemplary solution deposition techniques for forming a light-emitting layer containing a compound of formula (I) include printing and coating techniques such spin-coating, dip-coating, roll-to-roll coating or roll-to-roll printing, doctor blade coating, slot die coating, gravure printing, screen printing and inkjet printing.

Coating methods, such as those described above, are particularly suitable for devices wherein patterning of the light-emitting layer or layers is unnecessary—for example for lighting applications or simple monochrome segmented displays.

Printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

The same coating and printing methods may be used to form other layers of an OLED including (where present) a hole injection layer, a charge transporting layer and a charge blocking layer.

### EXAMPLES

### Compound Example 1

Ligand Intermediate 1 was prepared according to the following reaction scheme:

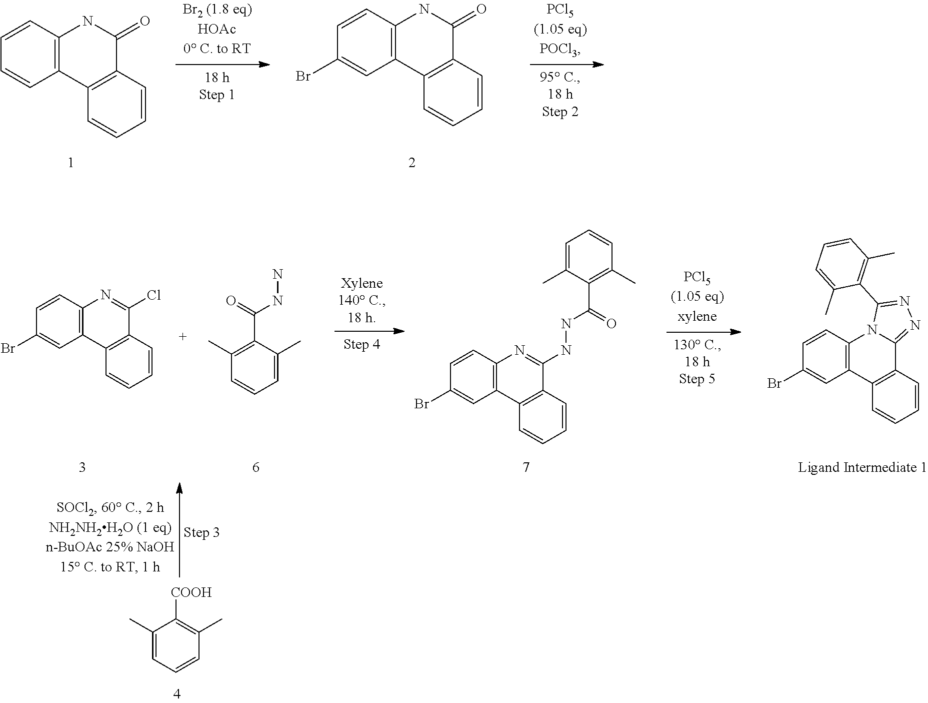

### Step-1: Synthesis of 2-Bromo-5H-phenanthridin-6-one (2)

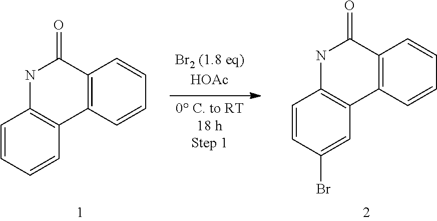 [SMILES: O=c1[nH]c2ccccc2c2ccccc12 ; O=c1[nH]c2ccc(Br)cc2c2ccccc12]

| | Quantity | Vol. | | | |
|---|---|---|---|---|---|
| Reagent | (g) | (mL) | MW | Moles | Eq. |
| 6-(5H)-Phenanthridinone | 100 | | 195.22 | 0.512 | 1 |
| Bromine | 147 | 46 | 159.81 | 0.922 | 1.8 |
| Acetic acid | | 1000 | | | |

### Apparatus Set-Up:

A 5 L 3-necked round-bottomed flask, equipped with a mechanical overhead stirrer, nitrogen inlet and exhaust.

### Experimental Procedure:

6-(5H)-Phenanthridinone (100 g, 0.512 mol) was taken in acetic acid (1 L).

The mixture was cooled to 0° C. using an ice bath.

Bromine (46 mL, 0.922 mol) was slowly added at 0° C.

The reaction was slowly warm to RT and stirred for 16 h.

After completion of the reaction, the mixture was carefully added to ice cold water (1 L) and stirred for 30 min.

The solid thus obtained was filtered, washed with 10% aqueous sodium thiosulphate solution (1 L) followed by water (1 L).

The solid thus obtained (150 g) was triturated with acetonitrile (300 mL) and filtered to afford 2-Bromo-5H-phenanthridin-6-one (2) as off white solid (130 g), 97.13% HPLC purity.

¹H-NMR (400 MHz, DMSO-d₆) δ [ppm] δ 7.29 (d, J=8.68 Hz, 1H), 7.64 (dd, J=2.12 Hz, 8.66 Hz, 1H), 7.67-7.69 (m, 1H), 7.83-7.87 (m, 1H), 8.31 (dd, J=1.2 Hz, 7.92 Hz, 1H), 8.56 (d, J=8.16 Hz, 1H), 8.58 (d, J=2.08 Hz, 1H), 11.80 (br, s, 1H).

### Step-2: Synthesis of 2-Bromo-6-chlorophenanthridine (3)

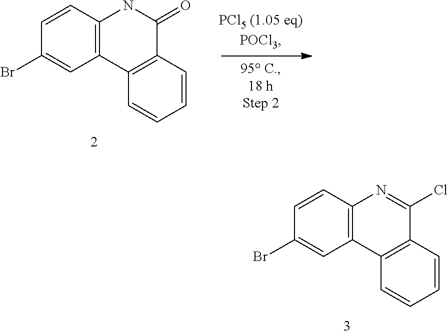 [SMILES: O=c1[nH]c2ccc(Br)cc2c2ccccc12 ; Clc1nc2ccc(Br)cc2c2ccccc12]

| | Quantity | Vol. | | | |
|---|---|---|---|---|---|
| Reagent | (g) | (mL) | MW | Moles | Eq. |
| 2-Bromo-5H- | 100 | | 274.11 | 0.364 | 1 |
| phenanthridin-6-one | | | | | |
| Phosphorus pentachloride | 79.8 | | 208.4 | 0.383 | 1.05 |
| Phosphorus oxychloride | | 700 | | | |

### Apparatus Set-Up:

A 5 L 3-necked round-bottomed flask, equipped with a mechanical overhead stirrer, reflux condenser, nitrogen inlet and exhaust.

### Experimental Procedure:

To a solution of 2-Bromo-5H-phenanthridin-6-one (100 g, 0.364 mol) in POCl₃ (700 mL), PCl₅(79.8 g, 0.364 mol) was added portion wise.

The mixture was heated at 95° C. for 18 h.

After completion of the reaction, POCl₃ was distilled off under vacuum.

The residue was carefully added to ice water (2 L) and stirred for an hour.

The solid thus obtained was filtered, washed with water to get 120 g of crude product.

The crude product was crystallized using hot toluene to obtain 70 g of intermediate 3 with 86% HPLC purity.

The product was further purified by silica column chromatography using 25 to 30% of ethyl acetate in hexane to afford 50 g of 2-Bromo-6-chlorophenanthridine (3) with 99.12% HPLC purity.

¹H-NMR (400 MHz, DMSO-d₆): δ [ppm] δ 7.91-7.95 (m, 3H), 8.03-8.07 (m, 1H), 8.42 (d, J=7.64 Hz, 1H), 8.96 (d, J=8.28 Hz, 1H), 9.04 (s, 1H).

### Step 3—Synthesis of Intermediate 6

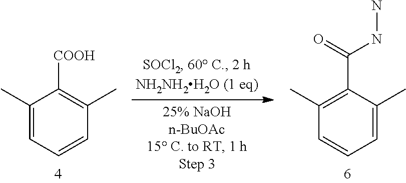

| | Quantity | Vol. | | | |
|---|---|---|---|---|---|
| Reagent | (g) | (mL) | MW | Moles | Eq. |
| 2,4,6-Trimethyl benzoic acid | 50 | | 150 | 0.333 | 1 |
| Thionyl chloride | | 100 | | | |
| Hydrazine hydrate | 16.6 | | 50 | 0.333 | 1.0 |
| 25% aqueous NaOH solution | | 400 | | | |
| 10% aqueous K₂CO₃ solution | | 60 | | | |
| n-Butyl acetate | | 400 | | | |

### Apparatus Set-Up:

A 3 L 3-necked round-bottomed flask, equipped with a mechanical overhead stirrer, nitrogen inlet and exhaust.

### Experimental Procedure:

A mixture of 2,4,6-Trimethyl benzoic acid (50 g, 0.333 mol) and thionyl chloride (100 mL) was heated at 60° C. for 2 h.

In-process check for acid chloride formation was confirmed by quenching an aliquot with methanol.

After complete conversion, excess thionyl chloride was removed under vacuum.

In another flask, hydrazine (16.6 g, 0.333 mol) was taken in mixture of 25% aqueous NaOH (400 mL), 10% K₂CO₃ solution (60 mL) and n-butyl acetate (400 mL).

The mixture was cooled to 15° C. and the acid chloride prepare above was slowly added.

The resultant mixture was stirred at 40° C. for an hour.

After completion of the reaction, the organic layer separated and concentrated.

The crude product (55 g) was triturated with ethyl acetate and filtered to obtain 43 g of intermediate 6.

¹H-NMR (400 MHz, DMSO-d₆): δ [ppm] 2.19 (s, 6H), 4.43 (s, br, 2H), 7.01-7.04 (m, 2H), 7.13-7.17 (m, 1H), 9.31 (s, br, 1H).

### Step 4—Synthesis of Intermediate 7

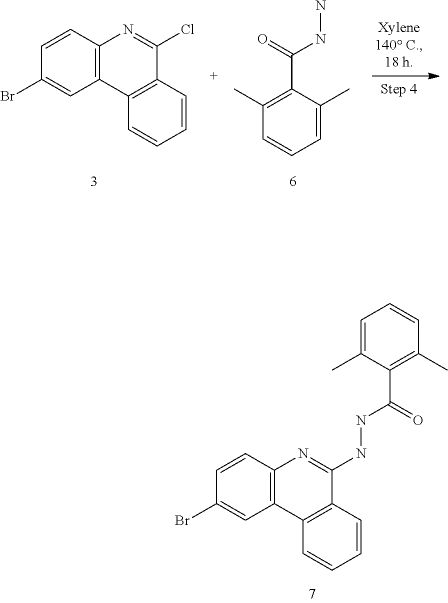

| | Quantity | Vol. | | | |
|---|---|---|---|---|---|
| Reagent | (g) | (mL) | MW | Moles | Eq. |
| Intermediate 3 | 50 | | 292.5 | 0.1709 | 1 |
| Intermediate 6 | 30.8 | | 164 | 0.188 | 1.1 |
| xylene | | 500 | | | |

### Apparatus Set-Up:

A 2 L 3-necked round-bottomed flask, equipped with a mechanical overhead stirrer, reflux condenser, nitrogen inlet and exhaust.

### Experimental Procedure:

A mixture of Intermediate 3 (50 g, 0.1709 mol) and Intermediate 6 (30.8 g, 0.188 mol) in xylene (500 mL) was heated at 140° C. for 18 h.

After completion of the reaction, it was cooled to room temperature and ethyl acetate (500 mL) was added and stirred for an hour.

The solid obtained was filtered to get 70 g of crude product.

The crude product thus obtained was stirred in ethyl acetate (500 ml) and filtered to obtain 55 g of intermediate 7 with 98.5% HPLC purity.

¹H-NMR (300 MHz, DMSO-d₆): δ [ppm] 2.29 (s, 6H), 7.04-7.30 (m, 4H), 7.71-8.01 (m, 4H), 8.65-8.86 (m, 3H), 10.50 (s, br, 1H).

### Step 5—Synthesis of Ligand Intermediate 1

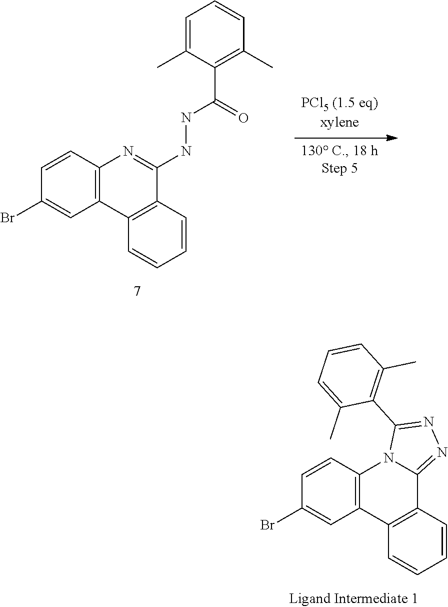 [SMILES: Cc1cccc(C)c1C(=O)NNc1nc2ccc(Br)cc2c2ccccc12 ; Cc1cccc(C)c1-c1nnc2c3ccccc3c3cc(Br)ccc3n12]

| | Quantity | Vol. | | | |
|---|---|---|---|---|---|
| Reagent | (g) | (mL) | MW | Moles | Eq. |
| Intermediate 7 | 55 | | 422 | 0.130 | 1 |
| Phosphorus pentachloride | 40.6 | | 208.4 | 0.195 | 1.5 |
| xylene | | 600 | | | |

### Apparatus Set-Up:

A 2 L 3-necked round-bottomed flask, equipped with a mechanical overhead stirrer, reflux condenser, nitrogen inlet and exhaust.

### Experimental Procedure:

Intermediate 7 (55 g, 1.0795 mol) was taken in xylene (600 mL).

Phosphorus pentachloride (40.6 g, 0.195 mol) was slowly added.

The reaction mixture was heated at 130° C. for 18 h.

After completion of the reaction, it was cooled to room temperature and water (200 mL) was added.

The reaction mixture was extracted with ethyl acetate (1 L), washed with water (500 mL), brine (500 mL), dried over sodium sulphate and concentrated.

The crude product was triturated with ethyl acetate (3 times) and filtered to obtain 37 g of Ligand Intermediate 1 with 99.31% HPLC purity.

It was dissolved in dichloromethane (500 mL), heated to 45° C., filtered at hot conditions and concentrated to 99.31% HPLC purity

¹H-NMR (400 MHz, CDCl₃): δ [ppm] 2.08 (s, 6H), 7.12 (d, J=9.2 Hz, 1H), 7.29 (d, J=8.0 Hz, 2H), 7.44-7.51 (m, 2H), 7.84-7.91 (m, 2H), 8.38-8.41 (m, 1H), 8.63 (d, J=2.0 Hz, 1H), 9.07 (d, J=7.2 Hz, 1H).

### Step 6—Synthesis of Ligand 1

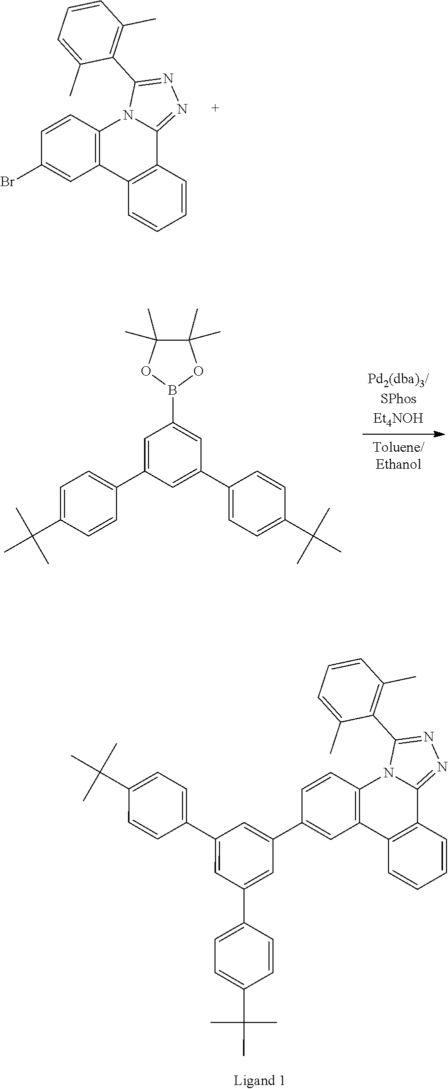

| | Quantity | Vol. | | Moles | |
|---|---|---|---|---|---|
| Reagent | (g) | (mL) | MW | (mmol) | Eq. |
| Ligand Intermediate 1 | 15.0 | | 402.30 | 37.3 | 1.0 |
| 3,5-(di-(4-t- | 17.8 | | 468.49 | 38.0 | 1.02 |
| butylphenyl)benzene | | | | | |
| boronic acid pinacol ester | | | | | |
| (D2PE) | | | | | |
| Pd₂(dba)₃ | 0.17 | | 915.74 | 0.19 | 0.005 |
| SPhos | 0.15 | | 410.53 | 0.37 | 0.01 |
| Et₄NOH (20% aq) | | 35 | | 49 | 1.3 |
| Toluene | | 250 | | | |
| Ethanol | | 75 | | | |

### Apparatus Set-Up:

A 1 L 3-necked round-bottomed flask, equipped with a mechanical overhead stirrer, reflux condenser, nitrogen inlet and exhaust.

### Experimental Procedure:

The reaction flask was charged with Ligand Intermediate 1, D2PE, SPhos, Toluene and Ethanol. The solution was bubbled with nitrogen for 1 hr, and then Pd₂(dba)₃ catalyst was added. The Et4NOH solution was then added to the flask and the mixture heated at 101° C. for 20 hr. The reaction mixture was cooled and poured into a separating funnel. The aqueous layer was separated and extracted with 100 mL Toluene. The combined organic solutions were washed with warm (60° C.) water (4×250 mL), dried over MgSO₄ and the solvent removed in vacuo. Repeated recrystallization from mixtures of Toluene and Heptane gave a white solid at 99.77% HPLC purity. Analysis by XRF indicated presence of residual bromide starting material, so the reaction procedure was repeated with the following reagents: 0.4 g D2PE, 0.025 g Pd₂(dba)₃, 0.015 g SPhos in 120 mL Toluene with 8 mL Et4NOH.

Purification of the product by column chromatography on silica, eluting with a mixture of ethyl acetate and dichloromethane, followed by trituration with Toluene/Heptane resulted in a white solid, yield 10.66 g (43%), 99.82% HPLC purity

NMR 1H NMR (600 MHz, THF): 6=8.98 (1H, d, J=1.9 Hz), 8.82 (1H, dd, J=7.7 Hz, J=1.4 Hz), 8.76 (1H, d, J=7.8 Hz), 7.96 (2H, d, J=1.6 Hz), 7.87 (1H, t, J=1.6 Hz), 7.77 (2H, td, J=8.3 Hz, J=1.8 Hz), 7.72-7.75 (1H, m), 7.68-7.72 (4H, m), 7.50-7.54 (4H, m), 7.46 (1H, t, J=7.8 Hz), 7.29-7.33 (3H, m), 2.08 (6H, s), 1.37 (18H, s)

### Step 6—Synthesis of Compound Example 1

| | Quantity | Vol. | | Moles | |
|---|---|---|---|---|---|
| Reagent | (g) | (mL) | MW | (mmol) | Eq. |
| Iridium(III)acetylacetone | 0.74 | | 489.54 | 1.5 | 1.0 |
| Ligand 1 | 5.0 | | 663.91 | 7.5 | 5.0 |
| pentadecane | / | 2.0 | / | / | / |

### Apparatus Set-Up:

A 25 mL Kjeldahl-style schlenk flask (with sidearm) with air condenser and connection to nitrogen/vacuum systems via 3-way tap. The flask is set up in a sand-bath for heating (finely divided sand contained in a GlasCol® heating mantle) on a magnetic stirrer.

### Experimental Procedure

Iridium (III) acetylacetonate and Ligand 1 were placed in the flask with a magnetic stirrer bar and the system was evacuated and backfilled with nitrogen three times. Pentadecane was degassed by bubbling with nitrogen for 15 min then added to the flask through a flow of nitrogen via the sidearm. The mixture was heated to 300° C. (sand bath temperature) for 25 hr. The melt was then cooled and extracted from the flask by dissolution in toluene. The crude product was purified by repeated column chromatography on silica (with mixtures of heptane/dichloromethane or dichloromethane/ethyl acetate), recrystallization (from toluene/acetonitrile) and column chromatography on C18-Si (eluting with a mixture of tetrahydrofuran/acetonitrile), giving a yellow solid. Yield 0.14 g (4%), 99.23% HPLC purity.

NMR: ¹H NMR (600 MHz, THF) 6=8.90 (3H, d, J=2.0 Hz), 7.94 (6H, d, J=1.6 Hz), 7.93 (3H, d, J=8.3 Hz), 7.86 (3H, t, J=1.6 Hz), 7.71-7.73 (3H, m), 7.69-7.71 (12H, m), 7.49-7.53 (12H, m), 7.36 (3H, t, J=7.8 Hz), 7.24 (3H, d, J=7.7 Hz), 7.20 (3H, d, J=8.8 Hz), 7.10-7.15 (3H, m), 7.10-7.15 (3H, m), 6.98 (3H, d, J=7.4 Hz), 2.22 (9H, s), 1.69-1.71 (9H, m), 1.37 (54H, s).

### Photoluminescent Properties

Photoluminescent properties of Compound Example 1 and Comparative Compounds 2 and 3 are given in Table 1. Photoluminescent spectra are shown in FIG. 2.

| Compound | Peak (nm) | CIE (x, y) |
|---|---|---|
| Compound Example 1 | 460 | 0.158, 0.230 |
| Comparative Compound 1 | 467 | 0.154, 0.280 |
| Comparative Compound 2 | 469 | 0.187, 0.380 |

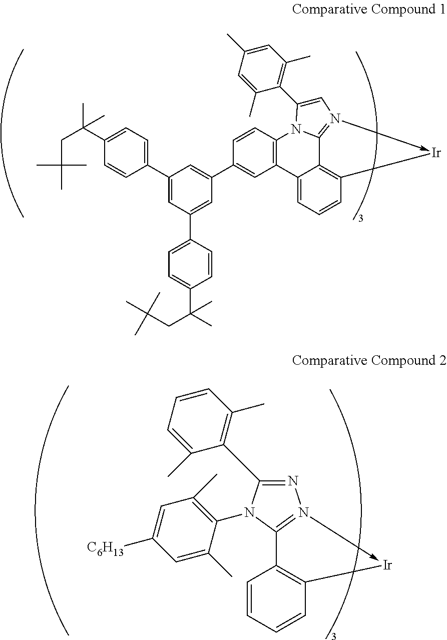

Compound Example 1 has a significantly shorter peak wavelength and a significantly lower CIE (y) coordinate as compared to Comparative Compound 2 or 3.

Compound Example 1 was combined with a green phosphorescent compound of tris(phenylpyridine) iridium (III) substituted with dendrons as described in WO 00/066552 and a conjugated polymer containing Red Phosphorescent Repeat Unit 1, illustrated below, in a ratio giving the same CIE coordinates as a black body emitting at 5000K. The CRI of the resulting spectrum was used to calculate the CRI as defined by the Commission International D'Eclairage under directive CIE 13.3-1995.

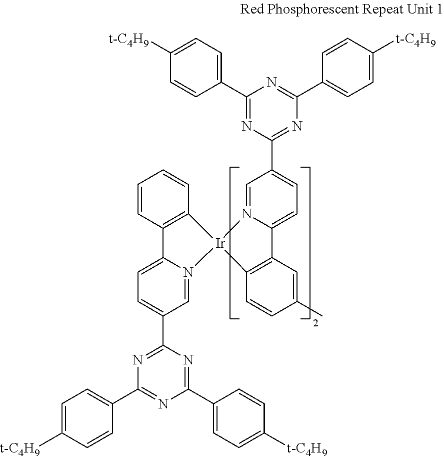

For comparison, CRI values of 5000K spectra were determined for white-emitting compositions as described above wherein Compound Example 1 was replaced with Comparative Compound 1 or 2.

With reference to Table 2, the 5000K white spectrum CRI for the composition containing Compound Example 1 is significantly higher than those containing Comparative Compound 1 or 2.

| Device | 5000K white spectrum CRI |
|---|---|
| Device Example 1 | 84 |
| Comparative Device 1 | 74 |
| Comparative Device 2 | 60 |

### Measurements

Photoluminescence spectra as described herein are measured by casting 5 wt % of the material in a polystyrene film onto a quartz substrate and measuring in a nitrogen environment using apparatus C9920-02 supplied by Hamamatsu.

CIE coordinates were measured using a Minolta CS200 ChromaMeter.

The lowest triplet excited state energy levels of a host material and a phosphorescent compound as described herein are as determined from the energy onset of its phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

HOMO and LUMO levels as described herein are as measured by square wave voltammetry (SWV).

Apparatus for HOMO or LUMO energy level measurements by SWV comprise a CHI 660D Potentiostat; a 3 mm diameter glassy carbon working electrode; a leak free Ag/AgCl reference electrode; Pt wire counter electrode; and a cell containing 0.1M tetrabutylammonium hexafluorophosphate in acetonitrile or acetonitrile:toluene (1:1).

To measure HOMO or LUMO of a polymer, ferrocene is added directly to a cell containing 0.1M tetrabutylammonium hexafluorophosphate in acetonitrile at the end of the experiment for calculation purposes where the potentials are determined for the oxidation and reduction of ferrocene versus Ag/AgCl using cyclic voltammetry (CV). The sample is dissolved in toluene (3 mg/ml) and spun at 3000 rpm directly on to the glassy carbon working electrode.

To measure HOMO or LUMO of a non-polymeric material, a cell containing 0.1M tetrabutylammonium hexafluorophosphate in acetonitrile:toluene (1:1) is used and Ferrocene is added to a fresh cell of identical solvent composition for calculation purposes where the potentials are determined for the oxidation and reduction of ferrocene versus Ag/AgCl using cyclic voltammetry (CV). The sample is dissolved in Toluene (3 mg/ml) and added directly to the cell

LUMO=4.8-E ferrocene (peak to peak average)−E reduction of sample (peak maximum)

HOMO=4.8-E ferrocene (peak to peak average)+E oxidation of sample (peak maximum)

The SWV experiment may be run at 15 Hz frequency; 25 mV amplitude and 0.004V increment steps under an Argon gas purge.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic white light-emitting device comprising an anode, a cathode and at least one light-emitting layer between the anode and the cathode, wherein a first light-emitting layer comprises a first light-emitting compound of formula (I): 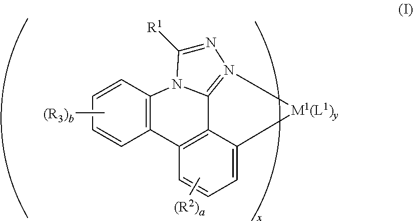
wherein R¹, R² and R³ independently in each occurrence is a substituent;
M¹ is a transition metal;
L¹ is a ligand other than a ligand of formula: 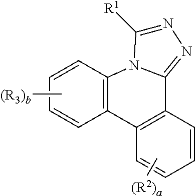
a is 0 or a positive integer;
b is 0 or a positive integer;
x is at least 1; and
y is 0 or a positive integer, a light-emitting layer of the device comprising at least one further light-emitting material.

2. A device according to claim 1 wherein M¹ is Ir³⁺.

3. A device according to claim 1 wherein x is 3 and y is 0.

4. A device according to claim 1 wherein R¹ is selected from the group consisting of:
C₁₋₂₀ alkyl wherein one or more non-adjacent C atoms of the C₁₋₂₀ alkyl may be replaced with —O—, —S— or —COO— and one or more H atoms may be replaced with F; and
a group of formula -(Ar¹)p wherein Ar¹ in each occurrence is a C₆₋₂₀ aryl group or a 5-20 membered heteroaryl group that may be unsubstituted or substituted with one or more substituents; and p is at least 1.

5. A device according to claim 1 wherein at least one of a and b is at least 1 and R² and R³ are independently in each occurrence selected from the group consisting of:
C₁₋₂₀ alkyl wherein one or more non-adjacent C atoms of the C₁₋₂₀ alkyl may be replaced with —O—, —S— or —COO— and one or more H atoms may be replaced with F; and
a group of formula -(Ar²)q wherein Ar² in each occurrence is a C₆₋₂₀ aryl group or a 5-20 membered heteroaryl group that may be unsubstituted or substituted with one or more substituents; and q is at least 1.

6. A device according to claim 1 wherein a is 0.

7. A device according to claim 1 wherein b is 1.

8. A device according to claim 1 wherein the compound of formula (I) has a photoluminescent spectrum having a peak of no more than 465 nm.

9. A device according to claim 1 wherein the device has 5000K white spectrum CRI of at least 80.

10. A device according to claim 1 wherein the first light-emitting layer is the only light-emitting layer of the device, the first light-emitting layer comprising the at least one further light-emitting material.

11. A device according to claim 1 wherein the device comprises at least one further light-emitting layer comprising a first further light-emitting material.

12. A device according to claim 11 wherein the first further light-emitting layer is between the anode and the first light-emitting layer.

13. A device according to claim 11 wherein the first light-emitting layer comprises a second further light-emitting material.

14. A device according to claim 1 wherein all light emitted by the device is phosphorescent.

15. A method of forming an organic light-emitting device according claim 1 comprising the step of depositing the first light-emitting layer over one of the anode and cathode, and depositing the other of the anode and cathode over the light-emitting layer.

16. A method according to claim 15 wherein the light-emitting layer is formed by depositing a solution comprising the compound of formula (I) and one or more solvents, and evaporating the one or more solvents.
